(19) United States
(12) Patent Application Publication
(10) Pub. No.: US 2009/0321762 A1
(43) Pub. Date: Dec. 31, 2009

(54) LIGHT EMITTING DIODE

(75) Inventor: Chia-Shou Chang, Taipei Hsien (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXCONN TECHNOLOGY CO., LTD., Taipei Hsien (TW)

(21) Appl. No.: 12/248,011

(22) Filed: Oct. 8, 2008

(30) Foreign Application Priority Data
Jun. 27, 2008 (CN) 200810068073.9

(51) Int. Cl. H01L 33/00

(52) U.S. Cl. 257/98; 257/E33.059

(57) ABSTRACT

An LED (20) includes a base (24), a chip (21) and an encapsulation (22). The base has a concave depression (240). The chip is mounted at a bottom of the concave depression. The encapsulation is received in the depression for encapsulating the chip. The chip includes a light emitting surface (210). The encapsulation includes a light output surface (25) over the light emitting surface. The light output surface defines a plurality of recesses (26) for respectively receiving a plurality of deposition points (28). The deposition points have a refractive index larger than that of the encapsulation.

### BACKGROUND

1. Field of the Invention

The present invention generally relates to a light emitting diode (LED), and more particularly to an LED which can provide a focused beam of light.

2. Description of Related Art

Light emitting diodes (LEDs) are commonly used as light sources in applications including lighting, signaling, signage and displays. The LED has several advantages over incandescent and fluorescent lamps, including high efficiency, high brightness, long life, and stable light output. The LED creates much higher illumination and space brightness with less electricity consumption.

A conventional LED generally includes a chip and an encapsulation encapsulating the chip. The encapsulation is made of a transparent or translucent epoxy resin and usually has an output surface over the chip. The chip emits light rays towards the output surface. Because the encapsulation has a refractive index larger than ambient air, the light rays incident on the output surface will be dispersed towards the ambient air over the output surface. However, in some applications, a light source using LED is required to generate a focused beam of light rays, such as an indicator.

Therefore, there is a need for an LED, which can provide a focused beam of light rays.

### SUMMARY

An LED according to an exemplary embodiment includes a base, a chip and an encapsulation. The base has a concave depression. The chip is mounted at a bottom of the concave depression. The encapsulation is received in the depression for encapsulating the chip. The chip includes a light emitting surface. The encapsulation includes a light output surface over the light emitting surface. The light output surface defines a plurality of recesses for receiving a plurality of deposition points. The deposition points have a refractive index larger than that of the encapsulation.

Other advantages and novel features of the present invention will become more apparent from the following detailed description of an embodiment/embodiments when taken in conjunction with the accompanying drawings.

### BRIEF DESCRIPTION OF THE DRAWINGS

FIG. 1 is a top plan view of an LED in accordance with an embodiment of the prevent invention.

FIG. 2 is a cross-sectional view of the LED shown in FIG. 1, along line II-II thereof.

FIG. 3 is similar to FIG. 2, but shows a light path of light rays emitted from a chip of the LED.

### DETAILED DESCRIPTION

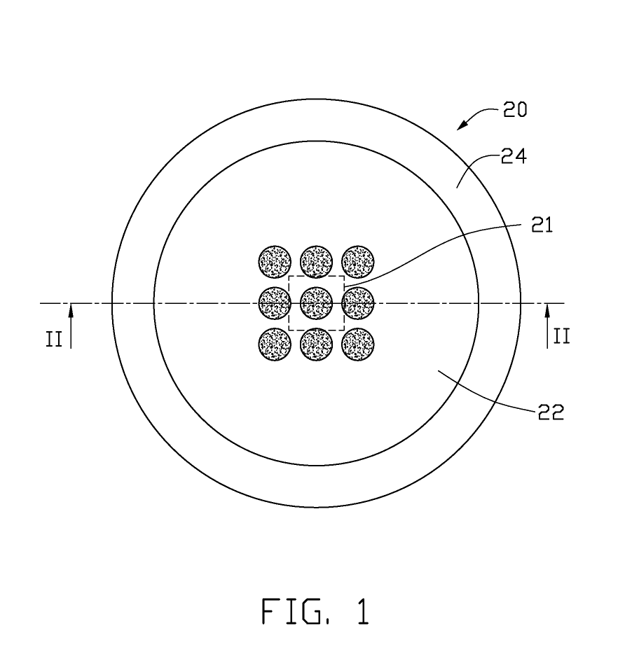

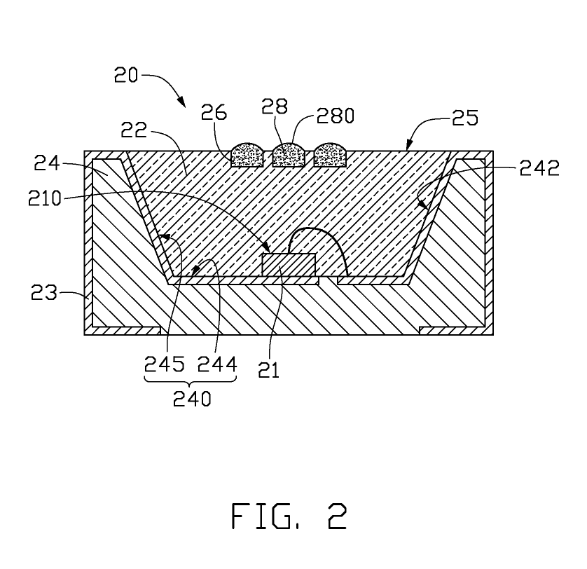

Referring to FIGS. 1 and 2, an LED 20 in accordance with an embodiment of the present invention is illustrated. The LED 20 comprises a chip 21, an encapsulation 22 and a concave base 24. The chip 21 is disposed on a top of the base 24 in a concave depression 240 thereof. The encapsulation 22 is received in the concave depression 240 of the base 24 for encapsulating the chip 21. The chip 21 is used to emit light rays. The light rays pass through the encapsulation 22 and finally reach an outside above the LED 20.

The chip 21 has a flat light emitting surface 210 on a top thereof. The light emitting surface 210 can generate light rays of different colors according to actual need, for example blue light rays, red light rays, or yellow light rays.

The base 24 has a cup-shaped configuration and has the concave depression 240 defined therein. The depression 240 has a trapeziform cross section 242. The depression 240 includes a flat bottom wall 244 and a sidewall 245 slantwise and upwardly extending from a periphery of the bottom wall 244 so that the depression 240 has a narrow bottom portion and a wide top portion.

The chip 21 is mounted on a center of the bottom wall 244 of the depression 240 via a silver paste or other conventional method. The chip 21 electrically connects to electric components 23 such as electrodes arranged in the base 24 so that the chip 21 is electrically connected to a printed circuit board on which the LED 20 is mounted, in which the electric elements 23 are soldered to the printed circuit board.

The encapsulation 22 is made of a first light penetrable material, such as acryl, silicone or epoxy resin. The encapsulation 22 serves to redirect the light rays from the chip 21 in addition to protecting the chip 21 from external physical shock. The encapsulation 22 fills in the concave depression 240, and adheres to the bottom wall 244 and the sidewall 245 of the concave depression 240. The chip 21 is covered by the encapsulation 22. The encapsulation 22 has a flat light output surface 25 over the light emitting surface 210 of the chip 21. The light output surface 25 is located on a top of the encapsulation 22.

A plurality of cylindrical recesses 26 are defined in the light output surface 25. The recesses 26 are distributed at an area where the light rays of the chip 21 can reach. The light rays radiate to the recesses 26, from which the light rays leaves the LED 20 into an outside of the LED 20. In the embodiment, the recesses 26 are distributed in a high density at a central area of the light output surface 25 over the chip 21, because the light rays of the chip 21 are focused on the central area of the light output surface 25. The recesses 26 are equidistantly spaced from each other. Each of the recesses 26 is filled with a deposition point 28 made of a second light penetrable material. The material of the deposition point 28 has a refractive index larger than that of the material of the encapsulation 22. The material of the deposition point 28 can be made of the first light penetrable material impregnated with particles such as titanic oxide of nanometer (TiO₂), or a combination of zirconia (ZrO) and bismuth trioxide (Bi₂O₃). A top portion of each deposition point 28 protrudes upwardly from the light output surface 25 and has an arched, convex surface 280. The deposition points 28 are arranged in rows and columns.

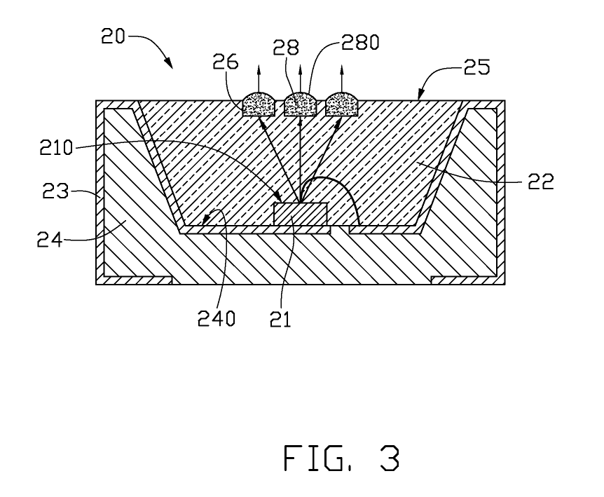

Referring to FIG. 3, in operation, light rays are emitted out from the light emitting surface 210 of the chip 21, then pass through the encapsulation 22, and then fall incident on the light output surface 25. Because the deposition points 28 each have a refractive index larger than that of the encapsulation 22, the light rays incident on the recesses 26 are absorbed by the deposition points 28, and then are converged towards a central region above the light output surface 25. Furthermore, because the deposition points 28 each have an arched, convex top surface 280, the light rays are further converged towards the central region above the light output surface 25 so that the LED 20 can generate a focused beam of light rays towards ambient air over the light output surface 25.

Moreover, the deposition points 28 in the recesses 26 facilitate extraction of light rays to the outside of the LED 20 and the light extraction efficiency of the LED 20 can be improved. The deposition points 28 have a refractive index which is larger than that of the encapsulation 22 so that light loss caused by total reflection can be greatly reduced.

The LED 20 can be produced by a method described below.

Firstly, a chip 21 and a base 24 are provided. The base 24 has a concave depression 240 defined therein. The chip 21 is disposed in the depression 240 with the chip 21 electrically connecting to the electric components 23 arranged in the base 24. The chip 21 is mounted on the base 24 via a silver paste or other conventional method.

Secondly, an encapsulation 22 of a first light penetrable material is disposed into the depression 240 of the base 24 to encapsulate the chip 21. Particularly, the first light penetrable material, such as silicone, is firstly heated up until the material is changed from solid into liquid, and then the liquefied material is poured into the depression 240 of the base 24 to form the encapsulation 22.

Thirdly, a plurality of recesses 26 are defined in the light output surface 25.

Fourthly, a second light penetrable material, which can be made of the first light penetrable material uniformly impregnated with particles such as titanic oxide of nanometer (TiO₂) or a combination of zirconia (ZrO) and bismuth trioxide (Bi₂O₃), is injected into the recesses 26 to form a plurality of deposition points 28. Thus, an LED 20 is formed.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An LED comprising:
a chip; and
an encapsulation made of a first light penetrable material and encapsulating the chip, wherein
the chip includes a light emitting surface, the encapsulation includes a light output surface over the light emitting surface, a plurality of deposition points made of a second light penetrable material are distributed in the light output surface, and the second light penetrable material has a refractive index larger than that of the first light penetrable material.

2. The LED as claimed in claim 1, wherein the deposition points are distributed at an area of the light output surface of the encapsulation from which the light rays of the chip radiate through the output surface to an outside of the LED.

3. The LED as claimed in claim 1 further comprising a base, wherein the base has a concave depression defined therein, and the chip is located on a center of the depression, and the encapsulation fills in the depression and encapsulates the chip.

4. The LED as claimed in claim 3, wherein the deposition points are distributed at a central area of the light output surface of the encapsulation over the chip.

5. The LED as claimed in claim 1, wherein the deposition points are spaced from each other, the deposition points are arranged crowdedly in rows and columns.

6. The LED as claimed in claim 1, wherein each of the deposition points has an arched, convex top surface.

7. The LED as claimed in claim 1, wherein a plurality of spaced recesses are defined in the light output surface of the encapsulation, and the deposition points are respectively filled in the recesses.

8. The LED as claimed in claim 7, wherein the recesses are cylindrical, and a top portion of each of the deposition points protrudes out from the light output surface of the encapsulation and has an arched, convex surface.

9. The LED as claimed in claim 1, wherein the first light penetrable material is made of a material selected from a group consisting of acryl, silicone and epoxy resin.

10. The LED as claimed in claim 9, wherein the second light penetrable material is made of the first light penetrable material impregnated with particles selected from a group consisted of titanic oxide of nanometer (TiO₂), and a combination of zirconia (ZrO) and bismuth trioxide (Bi₂O₃).

11. An LED comprising:
a base having a concave depression;
a chip mounted at a bottom of the concave depression;
an encapsulation received in the depression and encapsulating the chip, wherein
the chip includes a light emitting surface, the encapsulation includes a light output surface over the light emitting surface, the light output surface defines a plurality of recesses for respectively receiving a plurality of deposition points, and the deposition points have a refractive index larger than that of the encapsulation.

12. The LED as claimed in claim 1, wherein the deposition points are distributed at a central area of the light output surface of the encapsulation over the chip.

13. The LED as claimed in claim 11, wherein a top portion of each of the deposition points protrudes out from the light output surface of the encapsulation and has an arched, convex surface.
